(19) United States
(12) Patent Application Publication
(10) Pub. No.: US 2013/0180570 A1
(43) Pub. Date: Jul. 18, 2013

(54) DISH RECEIVER SYSTEM FOR SOLAR POWER GENERATION

(71) Applicant: GOSSAMER SPACE FRAMES, Huntington Beach, CA (US)

(72) Inventor: Glenn A. Reynolds, Laguna Hills, CA (US)

(73) Assignee: GOSSAMER SPACE FRAMES, Huntington Beach, CA (US)

(21) Appl. No.: 13/739,550

(22) Filed: Jan. 11, 2013

Related U.S. Application Data
(60) Provisional application No. 61/586,017, filed on Jan. 12, 2012.

(51) Int. Cl. H01L 31/058; H01L 31/052; F03G 6/06; F24J 2/12

(52) U.S. Cl. CPC H01L 31/058; F24J 2/12; H01L 31/0525; F03G 6/06
USPC 136/248; 126/692; 126/634; 126/651; 136/246; 126/694; 60/641.15

(57) ABSTRACT

A solar reflective assembly includes a plurality of reflective segments radially configured to collectively at least partially define a dish-shaped reflector having a center axis, each reflective segment having a generally conical shape and being discontinuous relative to the conical shape of an adjacent reflective segment, and an elongated receiver having a length generally extending in a direction of the center axis. Each reflective segment reflects and focuses sunlight on the receiver along the length of the receiver.

### RELATED APPLICATIONS

The present application claims the benefit of U.S. Provisional Application Ser. No. 61/586,017, flied on Jan. 12, 2012, the entire disclosure of which is incorporated herein by reference.

### FIELD

This disclosure generally relates to concentrated solar power generation systems, and more particularly, to a dish receiver system for solar power generation.

### BACKGROUND

Reflective solar power generation systems generally reflect and/or focus sunlight, onto one or more receivers. A receiver may include photovoltaic or concentrated photovoltaic cells for producing electricity. Alternatively, the receiver may carry a heat transfer fluid (HTF). The heated RIF is then used to generate steam by which a steam turbine, is operated to produce electricity with a generator. One type of reflective solar power generation system may use a number of spaced apart reflective panel assemblies that surround a central tower and reflect sunlight toward the central tower. Another type of reflective solar power generation system may use parabolic-shaped reflective panels that focus sunlight onto a receiver at the focal point of the parabola defining the shape of the reflective panels.

### BRIEF DESCRIPTION OF THE DRAWINGS

FIG. 1 shows a dish receiver system for solar power generation according to one embodiment.

FIG. 2 shows a dish receiver system for solar power generation according to one embodiment.

FIG. 3 shows a dish receiver system for solar power generation according to one embodiment.

FIG. 4 shows a schematic diagram of a reflective dish for a dish receiver system according to one embodiment.

FIG. 5 shows a schematic cross-sectional diagram of a section of the reflective dish of FIG. 4.

FIG. 6 shows a schematic cross-sectional diagram of a section of the reflective dish of FIG. 4.

FIG. 7 shows a reflective segment of a reflective dish for a dish receiver system according to one embodiment.

FIG. shows a schematic diagram of a receiver for a dish receiver system according to one embodiment.

FIG. 9 shows a schematic diagram of a receiver tube for a dish receiver system according to one embodiment.

FIG. 10 shows a schematic view of a reflective dish for a dish receiver system according to one embodiment.

FIG. 11 shows a perspective view of a reflective dish for a dish receiver system according to one embodiment.

FIG. 12 shows a schematic cross-sectional diagram of the reflective dish of FIG. 11.

FIG. 13 shows a schematic cross-sectional diagram of a reflective dish for a dish receiver system according to one embodiment.

FIG. 14 shows a perspective view of a support structure for a dish receiver system according to one embodiment.

### DETAILED DESCRIPTION

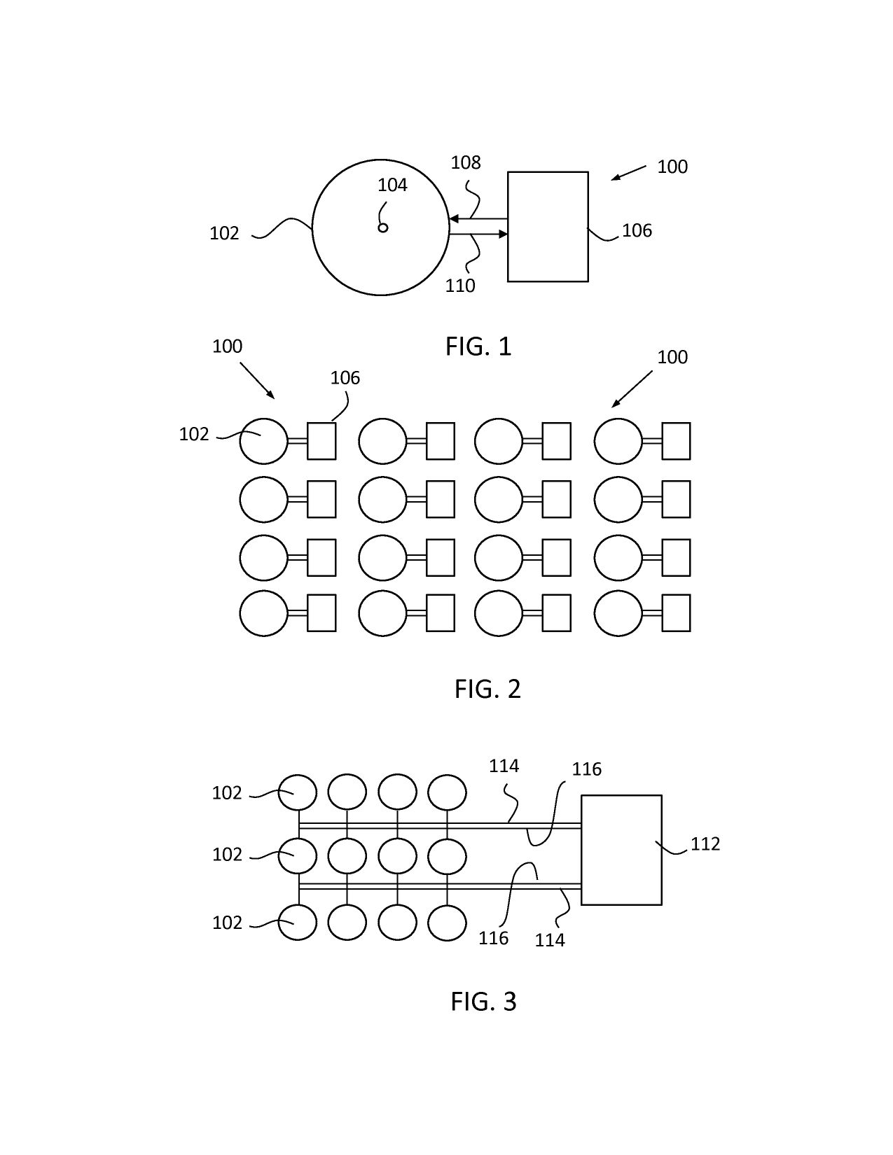

Referring to FIG. 1, a dish receiver system 100 according to one embodiment is shown. The dish receiver system 100 includes a reflective dish 102 that focuses sunlight onto a receiver tube 104. The receiver tube 104 receives a cold heat transfer fluid (HTF) from a power generation system 106 with a supply conduit 108. The power generation system 106 may include one or more steam turbines and one or more electrical generators for producing electricity. The HTF is then heated by the focused sunlight to a certain temperature (hot HTF) depending on the type of HTF used. For example, the HTF may be heated to about 300-400° C. (570-750° F.) if the HTF is an oil and to about 500-800° C. (930-1480° F.) if the HTF is a salt (i.e., molten salt when heated by the reflective dish 102). The hot. HTF is then provided to the power generation system 106 with a return conduit 110. The heat of the hot HTF is used to generate steam in the power generation system 106 to operate a generator to produce electricity. Alternatively, the receiver tube 104 may be a beam or a support structure on which a plurality of photovoltaic cells and/or concentrated photovoltaic cells (i.e., use concentrated or focused sunlight to generate electricity) may be mounted to generate electricity by receiving focused sunlight from the reflector dish 102. In the following examples, dish receiver systems utilizing an HTF to generate electricity are described in detail. However, the apparatus, the methods, arid the articles of manufacture described, herein are not limited in this regard.

As shown in FIG. 1, the dish receiver system 100 may be a single unit that can generate power without cooperating with other dish receiver systems. Alternatively, a solar power generation system may include a plurality of independently operated dish receiver systems 100 as shown in FIG. 2. The number of dish receiver systems 100 and arrangement thereof may depend on the characteristics of the area in which the dish receiver system 100 is installed. Such area characteristics may include the size of the area and/or terrain features.

According to another embodiment shown in FIG. 3, a solar power generation system may include a plurality of reflective dishes 102 that are operatively coupled to a power generation system 112. Each of the reflective dishes 102 may receive cold HTF from the power generation system 112 with supply conduits 114 and heat the cold HTF to produce a hot HTF. The hot HTF from the receiver of each reflective dish 102 is then provided to the power generation system 112 with return conduits 116. The power generation system 112 may then generate electricity by using the hot HTF as described above. A dish receiver system and/or the power generation system using one or more reflective dishes as described in detail below may not be limited to the examples described herein and may be in any configuration. Thus, while the above examples may describe various dish receiver systems and/or power generation systems that use a reflective dish receiver, the apparatus, the methods, and the articles of manufacture described herein are not limited in this regard.

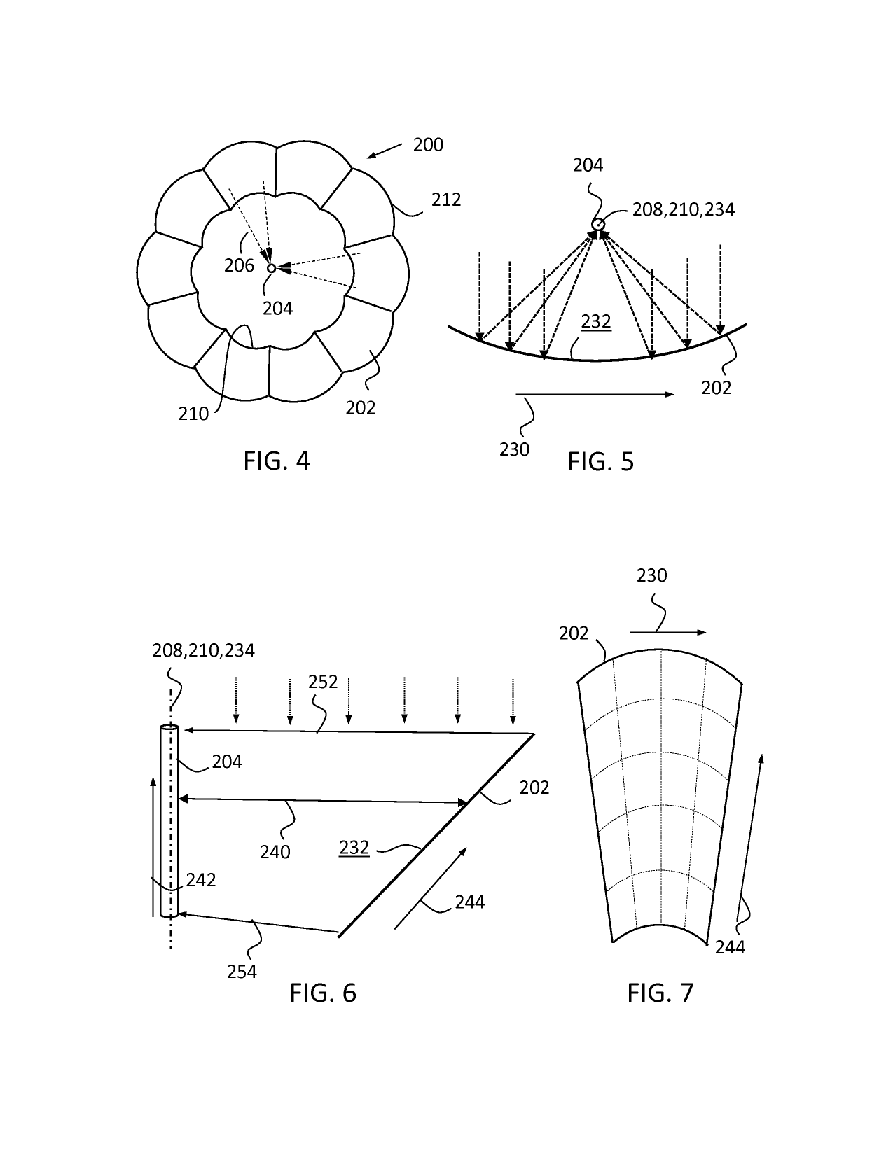

Referring to FIG. 4, a reflective dish 200 according to one example is shown. The reflective dish 200 includes a plurality of conical segments 202 that are radially arranged to collectively define the reflective dish 200. In the example of FIG. 4, the curvature of each conical segment 202 is exaggerated to illustrate the general shape of the reflective dish 200 and the conical segments 202. The reflective dish of FIG. 4 is shown to have ten conical segments 202. However, any number of conical segments may be used. Each conical segment 202 extends from an inner rim 210 toward an outer rim 212 of the conical reflective dish 200. Each conical segment 202 reflects and focuses sunlight, which is shown with rays 206, on a receiver tube 204 that is generally located along a center axis 208 (shown in FIGS. 5 and 6) of the reflective dish 200. Although FIG. 4 shows conical segments 202 located adjacent to each other to form the reflective dish 200 a reflective dish according to the disclosure may have fewer conical segments that are positioned at different radial locations. For example, a reflective dish according to the disclosure may have four conical segments placed at quadrants of the reflective dish with large gaps between the conical segments. Furthermore, a reflective dish according to the disclosure may have shapes other than generally circular. For example, a reflective dish may be triangular, rectangular, oval, hexagonal, etc. Accordingly each conical segment will be shaped to collectively form the general shape of the reflective dish.

FIG. 5 shows a cross-section of a conical segment 202. The cross-sectional view shown in FIG. 5 is taken from a plane that is perpendicular to the receiver tube 204 and intersects the receiver tube 204 and the conical segments 202. Each conical segment 202 may be generally parabolic in the tangential direction 230, which may be defined as a direction that is tangential to any point on a circle that generally defines a circumference of the reflective dish 200. The surface 232 of each conical segment 202 that faces the receiver tube 204 is reflective. For example, the surface 232 may be a mirror, constructed from a polished metal such as aluminum, or made from a reflective film mounted on a flexible substrate. Mathematically considered, each of the parabolic cross sections of the conical segment 202 reflects and focuses sunlight on a focal point on the center axis 208. Therefore, the entire conical segment 202 considering all cross sections of the cortical segment 202) focuses sunlight onto the receiver tube 204 along a focal line (i.e., defined by the focal points). Therefore, each conical segment 202 functions similar to a reflective parabolic trough.

FIG. 6 shows another cross-section of conical segment 202. The cross-sectional view shown in FIG. 6 is taken from a plane on which the center axis 208 lies. The distance 240 between the surface 232 of each conical segment 202 and the center axis 208 increases in an upward direction 242 along the center axis 208. Furthermore, each conical segment 202 is linear in cross section in a lengthwise direction of the conical segment 202 as shown by the arrow 244. Accordingly, to uniformly focus sunlight onto the receiver tube 204 from each conical segment 202, the parabolic shape of each conical segment 202 expands in the direction 244 as shown in FIG. 7. In other words, each conical segment 202 may be shaped similar to a tapered parabolic trough, where the tapering of the trough is due to the expansion of the parabola that generally defines the shape of the trough in the direction 244.

The center axis 208 of the reflective dish 200 also generally defines the focal line 210 of each conical segment 202 (shown in FIGS. 5 and 6). The receiver tube 204 is positioned relative to the conical segments 202 such that the longitudinal axis 234 of the receiver tube 204 is generally aligned, i.e., coaxial, with the center axis 208 and/or the focal line 210 (shown in FIGS. 5 and 6). Accordingly, each conical segment 202 reflects and focuses sunlight onto the receiver tube 204 along the focal line 210. Thus, each point on the surface 232 of each cortical segment 202 may reflect and focus sunlight onto a point along the focal line 210. For example, a focal line 210 produced by the conical segment 202 shown in FIG. 6 may be defined by all of the reflected rays within the reflected rays 252 and 254.

Referring to FIG. 8, sunlight that is reflected and focused by each reflective segment 202 may not reach the center axis 208, the focal line 210, and/or the longitudinal axis 234 because the reflected sunlight is intercepted by the outer surface 262 of the receiver tube 204. Accordingly, each conical segment 202 generates a focal band 260 on the corresponding outer surface 262 of the receiver tube 204 to heat the receiver tube 204. The focal band 260 is shown in FIG. 8 to be rectangular. However, the focal band 260 may have any elongated shape. Thus, all of the conical segments 202 of the conical dish 200 generate adjacent and/or overlapping focal, bands 260 on substantially the entire outer surface 262 of the receiver tube 204 to heat substantially the entire outer surface 262 of the receiver tube 204.

An example of a receiver tube 204 is shown in FIG. 9. The receiver tube 204 may include an inner tube 280 that may be coaxially located inside an outer tube 282. Accordingly, the inner tube 280 and the outer tube 282 may have generally the same longitudinal axis 234. Cold HTF is provided to the inner tube 280 such that it flows from the bottom of the inner tube 280 to the top of the inner tube 280. The top of the inner tube 280 is open and the top of the outer tube 282 is closed such that the cold HTF flows out of the inner tube 280 and into the outer tube 282 or into the annular space between the outer tube 282 and the inner tube 280. As the cold HTF flows from the top of the inner tube 280 and down the outer tube 282, heat from the outer surface 262 (shown in FIG. 8) of the receiver tube 204 is transferred to the. HTF to heat the HTF. As described in detail above, the hot HTF may have a temperature ranging from about 300-800° C. (570-1480° F.) depending on the type of HTF used. The hot HTF flows down the outer tube 282 and is transferred to a power generation system, in which the heat from the hot HTF may be used to produce steam to operate one or more steam turbines, which in turn may operate one or more electric generators to generate electricity. The receiver tube 204 may also include a generally transparent outer tube, such as a glass tube 284 to reduce heat loss due to convection.

As described above, the hot HTF in the outer tube 282 surrounds the cold HTF of the inner tube 280. Accordingly, the hot HI may transfer heat to the cold HTF inside the inner tube 280 to preheat the cold HTF. As a result, the hot HTF may also be cooled by the cold HTF. The exchange of heat between the cold HTF and the hot HTF may be used to regulate the temperature of the hot HTF by adjusting the flow rate of the HTF through the inner tube 280 and/or the outer tube 282. Furthermore, the sizes, shapes, and any configuration of the inner tube 280 and/or the outer tube 282 may be determined, so that preferred operating temperatures are achieved for the hot HTF for a range of flow rates. Further yet, the receiver tube may include, one or more valves to control the flow of the cold HTF and/or the hot HTF to regulate the operating temperature of the hot HTF.

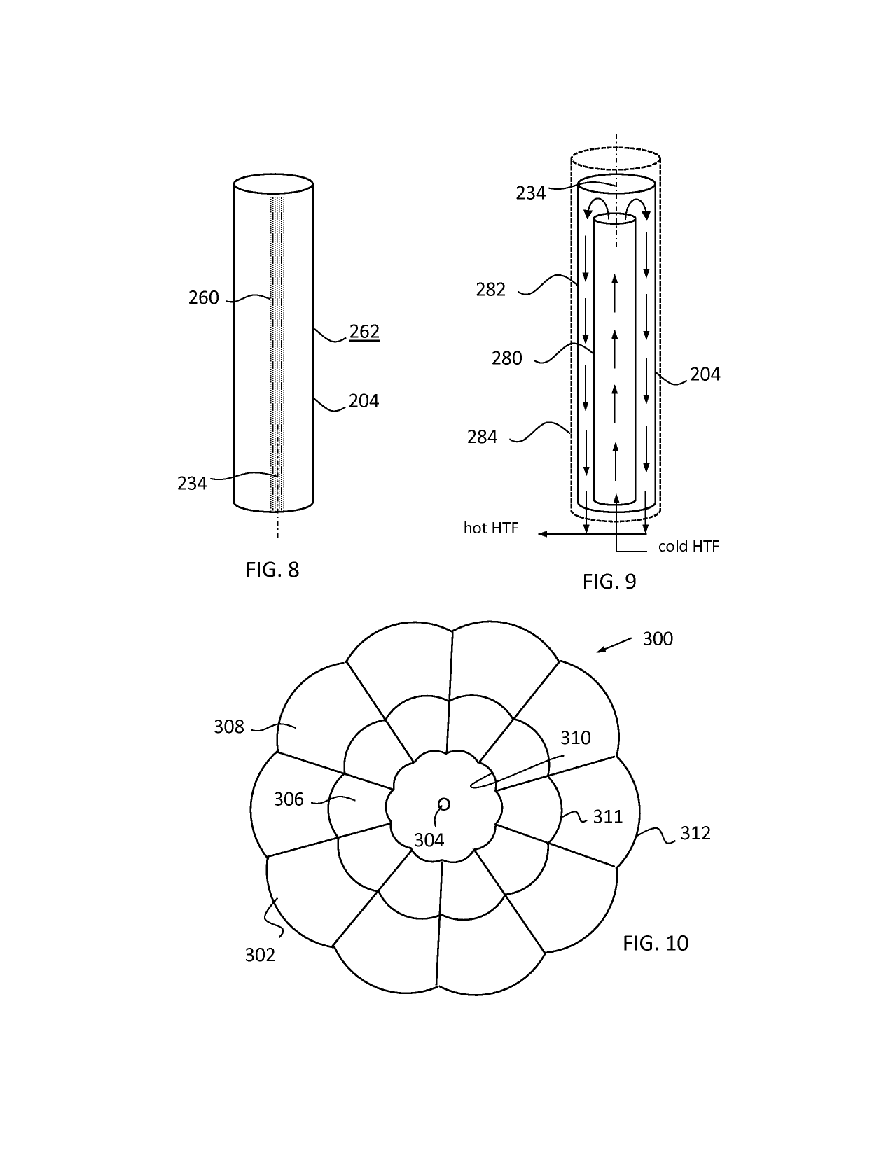

Referring to FIG. 10, a reflective dish 300 according to another example is shown. The reflective dish 300 includes a plurality of conical segments 302 that are radially arranged to collectively define the reflective dish 300. In the example of FIG. 10, the curvature of each conical segment 302 is exaggerated to illustrate the general shape of the reflective dish 300 and the conical segments 302. The reflective dish 300 of FIG. 10 is shown to have ten conical segments 302. However, any number of conical segments 302 may be provided. The conical segments 302 are arranged in two radial rows to define a first radial row of first conical segments 306 and a second radial raw of second conical segments 308. Each first conical segment 306 extends from an inner rim 310 of the reflective dish 300 to a connecting region 311 between the first conical segment 306 and a second- conical segment 308 that is located in generally the same radial location as the first conical segment 306. The connecting region 311 may include a gap or be gapless. Each second conical segment 308 extends from the connecting region 311 to an outer rim 312 of the reflective dish 300. The first and second conical segments 306 and 308, respectively, are similar in many respects to the conical segments 202 of the reflective dish 200 as described above and shown in FIGS, 4-7. Therefore, a detailed description of the conical segments 302 is not provided for brevity.

The first conical segments 306 may be similar in shape, size and/or configuration. The second conical segments 30$ may be similar in shape, size and/or configuration. However, the first conical segments 306 may have different Shape, size and/or configuration than the second conical segments 308. Although each first conical segment 306 is shown to be arranged in tandem with a second conical segment 308, the first conical Segments 306 and the second conical segments 308 may be arranged in any configuration. For example, each first conical segment 306 may be staggered relative to one or more second conical segments 308. In the example of FIG. 10, the dish 200 includes ten of the first conical segments 306 and ten of the second conical segments 308. However, in other examples, a dish according to the disclosure may include a different number of first conical segments than the second conical segments. Each conical segment 306 and 308 reflects and focuses sunlight onto a receiver tube 304 to form a focal band on an outer surface of the receiver tube as described in detail above.

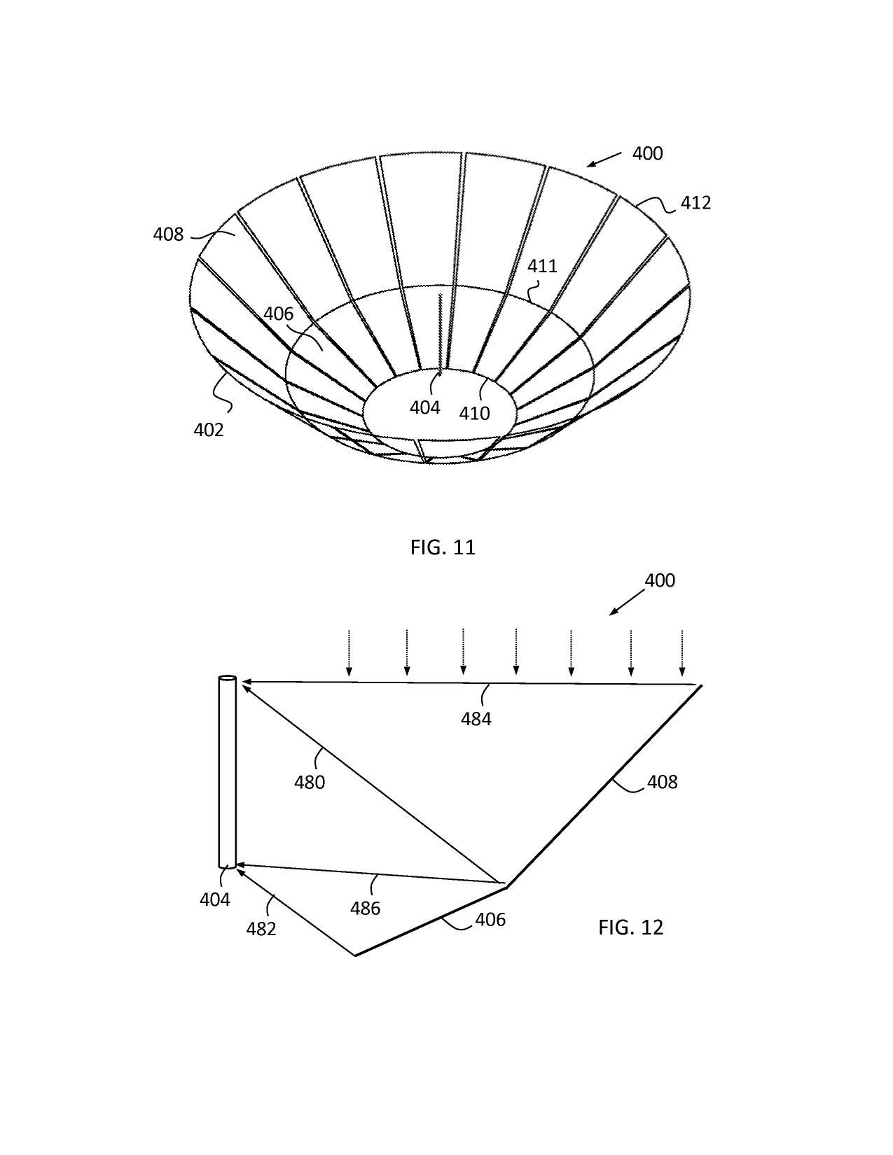

Referring to FIGS. 11 and 12, a reflective dish 400 according to another example is shown. The reflective dish 400 includes a plurality of conical segments 402 that are radially arranged to collectively define the reflective dish 400. The reflective dish 400 of FIG. 11 is shown to have eighteen conical segments 402. However, any number of conical segments may be provided. The conical segments 402 are arranged in two radial rows to define a first radial row of first conical segments 406 and a second radial row of second conical segments 408. The conical segments 406 extend from an inner rim 410 of the reflective dish 400 to a connecting region 411 between the conical segment 406 and the conical segment 408. The connecting region 411 may include a gap or be .gapless. The conical segments 408 extend from the connecting region 411 to an outer rim 412 of the reflective dish 400. Thus, the reflector dish 400 is similar in many respects to the reflector dish 300 described above, except that the reflective dish 400 includes eighteen conical segments 402 rather than ten conical segments 302, The conical segments 402 are similar in many respects to the conical segments 202 of the reflective dish 200 as described above and shown in FIGS 4-7. Therefore, a detailed description of the conical segments 402 is not provided for brevity.

Referring to FIG. 12, each conical segment 406 and 408 reflects and focuses sunlight onto a receiver tube 404 to form a focal band on an outer surface of the receiver tube as described in detail above. As shown in FIG. 11, each first conical segment 406 is configured in tandem with a second. conical segment 408. Accordingly, as shown in FIG. 12, the focal band generated on the receiver tube 404 by each of the first conical segments 406 and each of the corresponding tandem, second conical segments 408 may generally overlap. The first conical segment 406 may generate a focal band defined by the boundary rays 480 and 482. The second conical segment 408 may generate an overlapping focal band defined by the boundary rays 484 and 486. The location and/or configuration (shape, size, parabolic shape, etc.) of each conical segment relative to the receiver tube 404 may determine the orientation angle of each conical segment relative to the horizontal when the center axis of the reflective dish 400 is vertical. The orientation angles of the first conical segment 406 and the second conical segment 408 may be determined so that the first conical segment and the second conical segment discreetly (i.e., in linear segments) define a parabolic shape for the reflective dish 400. The number of conical segments, the number of radial rows of conical segments, the configuration of each conical segment, and/or the arrangement of the conical segments in a reflective dish may be determined so that a preferred amount of thermal energy is generated by a reflective dish according to the disclosure.

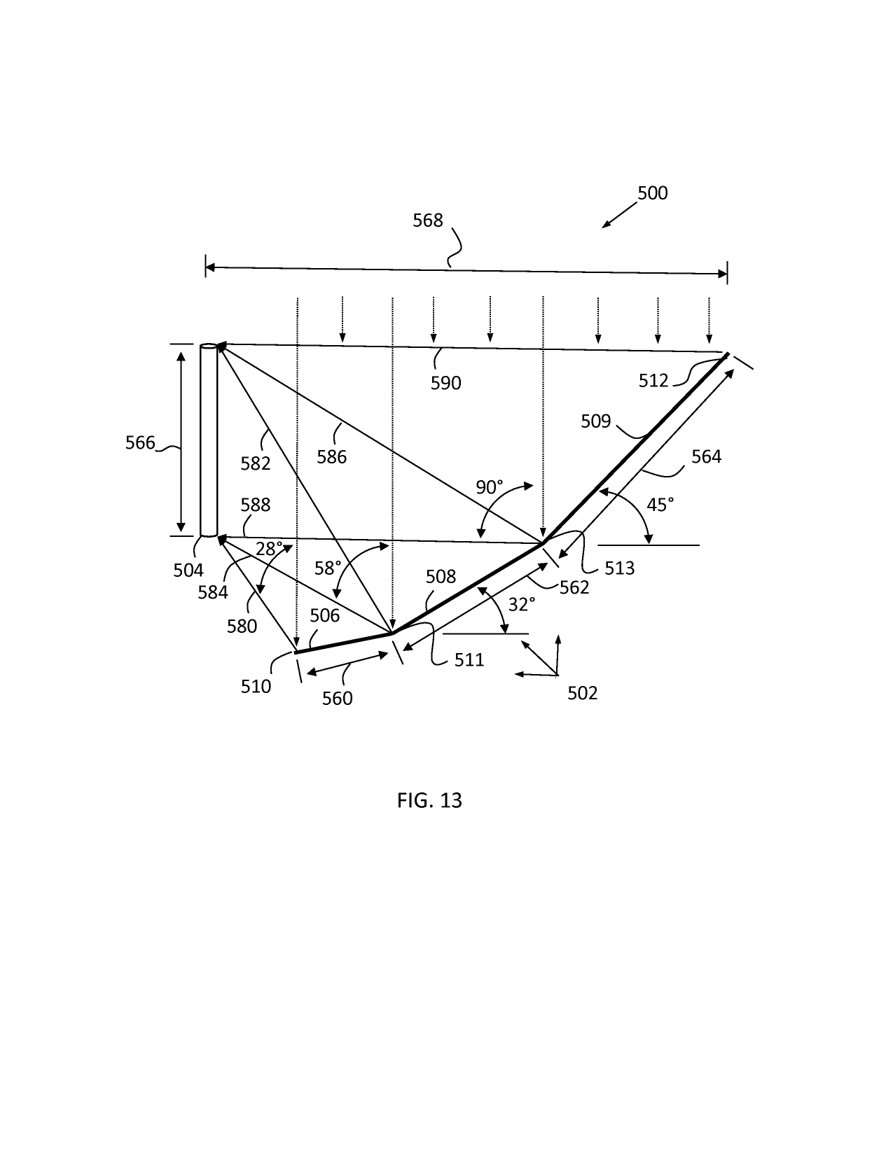

Referring to FIG. 13, a cross section of a reflective dish 5.00 according to another example is shown. The reflective dish 500 includes a. plurality of conical segments 502 that are radially arranged to collectively define the reflective dish 500. The conical segments 502 are arranged in three radial rows to define a first row of first conical segments 506, a second row of second conical segments 508 and a third row of third conical segments 509. The conical segments 506 extend from an inner rim 510 of the reflective dish 500 to a first connecting region 511 between the conical segment 506 and the conical segment 508. The first connecting region 511 may include a gap or be gapless. The conical segments 508 extend from the first connecting region 511 to a second connecting region 513 between the conical segments 508 and the conical segments 509. The second connecting region 513 may include a gap or be gapless. The conical segments 509 extend from the second connecting region 513 to an outer rim 512 of the reflective, dish 500. Thus, the reflective dish 500 is similar in many respects to the reflective dish 400 described above, except that the reflective dish 500 includes three radial rows of conical segments. The conical segments 502 are similar in many respects to the conical segments 202 of the reflective dish 200 as described above and shown in FIGS. 4-7. Therefore, a detailed description of the conical segments 502 is not provided for brevity.

Each of the conical segments 506, 508 and 509 reflects and focuses sunlight onto a receiver tube 504 to form a focal band on an outer surface of the receiver tube as described in detail above. As shown in FIG. 13, conical segments 506, 508 and 509 that are radially similarly located are configured in tandem. Accordingly, the focal band generated on the receiver tube 504 by each of the first conical segments 506 and the corresponding tandem second conical segment 508 and third conical segment 509 may generally overlap. The first conical segment 506 may generate a focal band defined by the boundary rays 580 and 582, the second conical segment 508 may generate an overlapping focal band defined by the boundary rays 584 and 586, and a third conical segment 509 may generate an overlapping, focal band defined by the boundary rays 588 and 590. The location and/or configuration (shape, size, parabolic shape, etc.) of each conical segment may determine the orientation angle of each conical segment relative to the horizontal, when the center axis of the reflective dish 500 is vertical. The orientation angles of the first conical segments 506, the second conical segments 508 and the third conical segments 509 may he determined so that the first conical segments 506, the second conical segments 508, and the third conical segments 509 discreetly (i.e., in linear segments) define a parabolic, shape for the reflective dish 500. The number of conical segments, the number of rows of conical segments, the configuration of each conical segment, and/or the arrangement of the conical segments in a reflective dish may be determined so that a preferred amount of thermal energy is generated by a reflective dish according to the disclosure.

According to the example shown in FIG. 13, the third conical segment 509 may have an orientation angle of about 45° and have a parabolic shape and configuration as described in detail herein such that sunlight is reflected and focused onto a receiver tube 504 at an incident angle of about 90°. The third conical segment may have a length 560 of about 5.6 meters (18 feet, 4 inches), The second conical segment 508 may have any orientation angle of about 32° and have a parabolic shape and configuration as described in detail herein such that sunlight is reflected and focused onto a receiver tube 504 at an incident angle of about 58°. The second conical segment 508 may have a length 562 of about 3.8 meters (12 feet, 4 inches). The first conical segment 506 may have an orientation, angle and have a parabolic shape and configuration as described in detail herein such that sunlight is reflected and focused onto a receiver tube 504 at an incident angle of about 28°. The first conical segment 506 may have a length 564 of about 1.9 meters (6 feet, 4 inches). The receiver tube 504 may have a diameter of about 90 mm (3.55 inches) and a length 560 of about 4 meters (13 feet). The upper edge of the third conical segment 509, i.e., the outer rime 512, may be horizontally aligned with the upper edge of the receiver tube 504. A radius 562 of the conical dish may be about 10 meters (34 feet) as defined by the distance between the upper edge of the third conical segment 509 and the upper edge of the receiver tube 504. The conical dish 500 may be capable of generating about 75-150 KW of power when coupled to a power generation system. The conical dish 500 represents one example of a conical dish according to the disclosure for generating power from sunlight. Thus, while the above example may describe a conical dish receiver systems and/or power generation systems that use a conical dish receiver, the apparatus, the methods, and the articles of manufacture described herein are not limited in this regard.

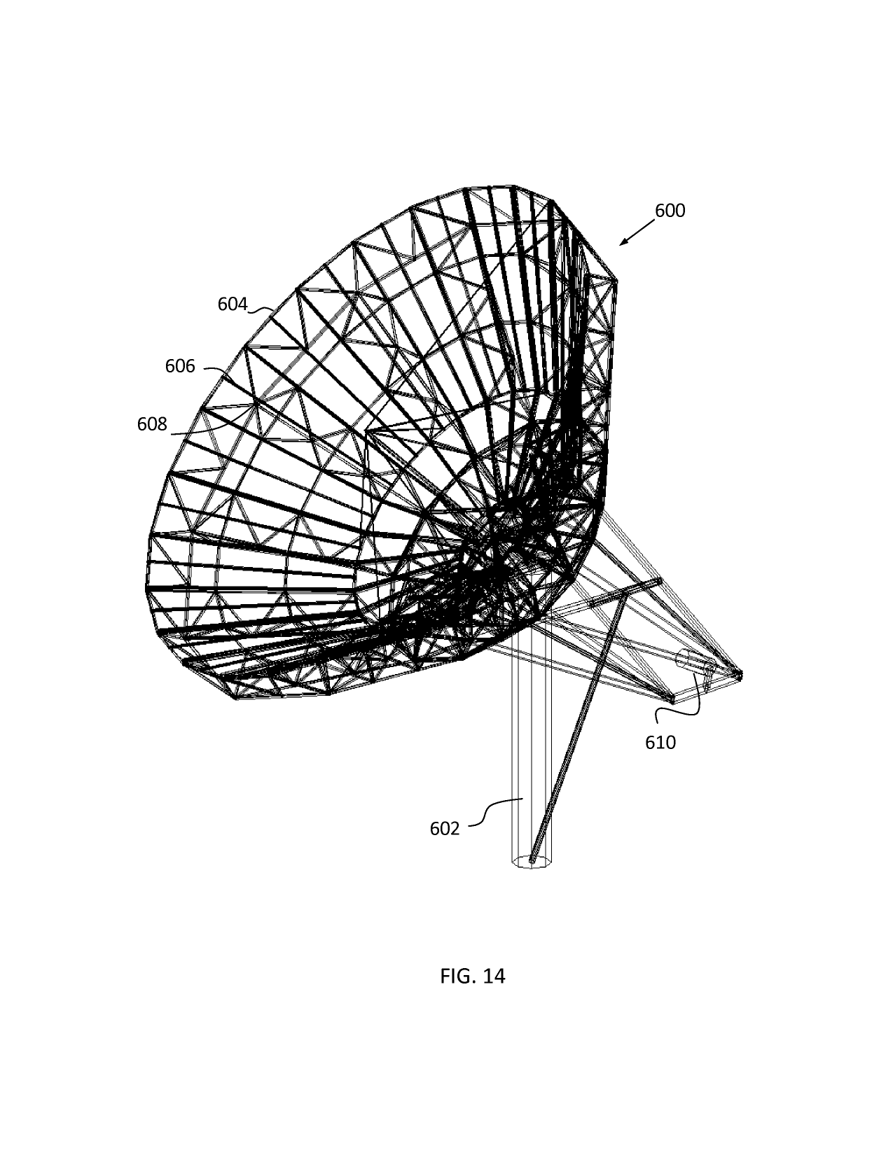

Referring to FIG. 14, a support structure 600 for a conical dish according to the disclosure is shown. The support structure 600 may include a support pylon 602 that is secured to the ground. The support pylon 602 may be constructed from concrete, one or more steel or aluminum beams (e.g., three support beams forming a tripod-shaped pylon), and/or any other material and/or configuration. A dish support frame 604 is mounted on the support pylon 602 and is rotational at least in elevation and azimuth relative to the pylon 602 so that the reflective dish may track the position of the sun. The dish support frame 604 may be constructed by a plurality of support members 606 (e.g., beams, rods, tubes, etc.) that are connected together with node connectors 608. Examples of node connectors and frames constructed with such node connectors are provided in detail in U.S. Pat. Nos.: 7,530,201; 7,578,109; and 7,581,862, the disclosures of which are incorporated herein by reference. A reflective dish as disclosed may be attached to the support frame 604. The reflective dish may have reflective surfaces including any backing substrates mounted to backing support structure (not shown). Examples of backing structures in the form of mini-trusses are provided in detail in U.S. Pat. Nos.: 8,132,391 and 8,327,604, the disclosures of which are incorporated herein by reference. The mini-truss backing structure is then mounted on the dish support frame 604. An example of mounting the backing structure on the dish support frame 606 is provided in detail in U.S. patent application Ser. No. 13/491,422, filed Jun. 7, 2012, the disclosure of which is incorporated herein by reference. While a particular example of a support structure for a conical dish according to the disclosure is provided above, the apparatus, the methods, and the articles of manufacture described herein are not limited, in this regard.

The support structure 600 may include a control system (not shown) for tracking the position of the sun and rotating the dish support frame 604 to continuously or discreetly point the reflective dish toward the sun. For example, the control system may rotate the dish by hydraulic actuation and/or using one or more electric motors. An exemplary control system by which the dish support frame 604 may be rotated to track the position of the sun and/or to control the thermal energy produced is provided in detail in U.S. patent application Ser. No. 13/588,387, filed Aug. 17, 2012, the disclosure, of which is incorporated by reference herein. The support structure 600 may also include at least one counterbalancing weight 610, which may be simply an object having no other function than to counterbalance the dish support structure 604. Alternatively, the weight 610 may be defined by any component, a plurality of components, or an entire power generation system and/or the control system for operating the dish receiver system.

Although a particular order of actions is described above, these actions may be performed in other temporal sequences. For example, two or more actions described above may be performed sequentially, concurrently, or simultaneously. Alternatively, two or more actions may be performed in reversed order. Further, one or more actions described above may not be performed at all. The apparatus, methods, and articles of manufacture described herein are not limited in this regard.

While the invention has been described in connection with various aspects, it will he understood that the invention is capable of further modifications. This application is intended to cover any variations, uses or adaptation of the invention following, in general, the principles of the invention, and including such departures from the present disclosure as come within the known and customary practice within the art to which the invention pertains.

What is claimed is:

1. A solar reflective assembly comprising:
a plurality of reflective segments radially configured to collectively at least partially define a dish-shaped reflector having a center axis, each reflective segment having a generally conical shape and being discontinuous relative to the conical shape of an adjacent reflective segment; and
an elongated receiver having a length generally extending in a direction of the center axis;
wherein each reflective segment reflects and focuses sunlight on the receiver along the length of the receiver.

2. The solar reflective assembly of claim 1, wherein the receiver comprises at least one tube configured to carry a heat transfer fluid, and wherein each reflective segment reflects and focuses sunlight on the receiver along the length of the receiver to heat the heat transfer fluid.

3. The solar reflective assembly of claim 1, the receiver comprising:
a first tube generally extending in a direction of the center axis; and
a second tube having a smaller diameter than the diameter of the first tube and located inside the first tube to define an annular space between the first tube and the second tube, the second tube having an open end and configured to carry a heat transfer fluid to the first tube through the open end;
wherein the heat transfer fluid is heated in the annular space by the sunlight reflected and focused onto the receiver by the plurality of reflective segments.

4. The solar reflective assembly of claim 1, the receiver comprising one or more photovoltaic cells, and wherein the one or more photovoltaic cells generate electricity by the sunlight reflected and focused on the receiver by the plurality of reflective segments.

5. The solar reflective, assembly of claim 1, the plurality of reflective segments comprising:
a first plurality of reflective segments radially configured to define a first radial row of the dish-shaped reflector; and
at least a second plurality of reflective segments radially configured to define a second radial row of the dish-shaped reflector;
wherein the first radial row is between the second radial row and the center axis.

6. The solar reflective assembly of claim 1, the plurality of reflective segments comprising;
a first plurality of reflective segments radially configured to define a first radial row of the dish-shaped reflector;
a second plurality of reflective segments radially configured to define a second radial row of the dish-shaped reflector; and
at least a third plurality of reflective segments radially configured to define a second radial row of the dish-shaped reflector;
wherein the second radial row is between the third radial row and the center axis; and
wherein the first radial row is between the second radial row and the center axis.

7. The solar reflective, assembly of claim 1, wherein each reflective segment has a generally parabolic cross-sectional shape, wherein the parabolic cross section shape expands in a direction along a length of the reflective segment, and wherein each reflective segment is linear along the length of the reflective segment.

8. A solar reflective assembly comprising:
a plurality of reflective segments radially configured to collectively at least partially define a dish-shaped reflector having a center axis, each reflective segment having a generally conical shape and being discontinuous relative to the conical shape of an adjacent reflective segment;
a first tube generally extending in a direction of the center axis;
a second tube having a smaller diameter than the diameter of the first tube and located inside the first tube to define an annular space between the first tube and the second tube, the second tube having an open end and configured to carry a heat transfer fluid to the first tube through the open end; and
wherein the heat transfer fluid is heated, in the annular space by sunlight reflected and focused onto the first tube by the plurality of reflective segments.

9. The solar reflective assembly of claim 8, the plurality of reflective segments comprising:
a first plurality of reflective segments radially configured to define a first radial row of the dish-shaped reflector; and
at least a second plurality of reflective, segments radially configured to define a second radial row of the dish-shaped reflector;
Wherein the first radial row is between the second radial row and the center axis.

10. The solar reflective assembly of claim 8, the plurality of reflective segments comprising:
a first plurality of reflective segments radially configured to define a first radial row of the dish-shaped reflector;
a second plurality of reflective segments radially configured to define a second radial row of the dish-shaped reflector; and
at least a third plurality of reflective segments radially configured to define a second radial row of the dish-shaped reflector;
wherein the second radial row is between the third radial row and the center axis; and
wherein the first radial row is between the second radial row and the center axis.

11. The solar reflective assembly of claim 8, wherein each reflective segment has a generally parabolic cross-sectional shape, wherein the parabolic cross section shape expands in a direction along a length of the reflective segment, and wherein each reflective segment is linear along the length of the reflective segment.

12. A solar power generation system comprising:
at least one solar reflective assembly comprising:
a plurality of reflective segments radially configured to collectively at least partially define a dish-shaped reflector having a center axis, each reflective segment having a generally conical shape and being discontinuous relative to the conical shape of an adjacent reflective segment; and
an elongated receiver having a length generally extending in a direction of the center axis, the receiver comprising at least one tube configured to carry a heat transfer fluid, wherein each reflective segment reflects and focuses sunlight on the receiver along the length of the receiver to heat the heat transfer fluid; and
at least one power generation system configured to receive the heated heat transfer fluid and generate electricity.

13. The solar power generation system of claim 12, the receiver comprising:
a first tube generally extending in a direction of the center axis; and
a second tube having a smaller diameter than the diameter of the first tube and located inside the first tube to define an annular space between the first tube and the second tube, the second tube having, an open end and configured to carry a heat transfer fluid to the first tube through the open end;
wherein the heat transfer fluid is heated in the annular space by the sunlight reflected and focused onto the receiver by the plurality of reflective segments.

14. The solar power generation system of claim 12, the plurality of reflective segments comprising:
a first plurality of reflective segments radially configured to define a first radial row of the dish-shaped reflector; and
at least a second plurality of reflective. segments radially configured to define a second radial row of the dish-shaped reflector;
wherein the first radial row is between the second radial row and the center axis.

15. The solar reflective assembly of claim 12, the plurality of reflective segments comprising:
a first plurality of reflective segments radially configured to define a first radial row of the dish-shaped reflector;
a second plurality of reflective segments radially configured to define a second radial row of the dish-shaped reflector; and
at least a third plurality of reflective segments radially configured to define a second radial row of the dish-shaped reflector;
wherein the second radial row is between the third radial row and the center axis; and
wherein the first radial row is between the second radial row and the center axis.

16. The solar power generation system of claim 12, wherein each reflective segment has a generally parabolic cross-sectional shape, wherein the parabolic cross section shape expands in a direction along a length of the reflective segment and wherein each reflective segment is linear along the length of the reflective segment.

17. The solar power generation system of claim 12, comprising a plurality of solar reflective assemblies, wherein the at least one power generation system is configured to receive the heated heat transfer fluid from the plurality of solar reflective assemblies and generate electricity.

18. The solar power generation system of claim 12, comprising a plurality of solar reflective assemblies and a plurality of power generation systems, wherein each solar reflective assembly is operatively coupled to a corresponding one of the power generation systems.

19. The solar power generation system of claim 12, wherein the at least one power generation system comprises a steam turbine configured to operate with steam generated from heating water with heat from the heated heat transfer fluid, and an electric generator operatively coupled to the steam turbine to generate electricity.

20. The solar power generation system of claim 12, a support structure configured to support the at least one solar reflective assembly and at least one component of the power generation system.
